(19) United States
(12) Patent Application Publication
(10) Pub. No.: US 2022/0068694 A1
(43) Pub. Date: Mar. 3, 2022

(54) WAFER PROCESSING METHOD

(71) Applicant: DISCO CORPORATION, Tokyo (JP)

(72) Inventors: Toshiyuki SAKAI, Tokyo (JP); Heidi LAN, Tokyo (JP)

(21) Appl. No.: 17/406,231

(22) Filed: Aug. 19, 2021

(30) Foreign Application Priority Data
Sep. 1, 2020 (JP) 2020-146652

(51) Int. Cl. H01L 21/683; H01L 21/78; H01L 21/67

(52) U.S. Cl. CPC H01L 21/6836; H01L 21/67132; H01L 21/78

(57) ABSTRACT

A wafer processing method for processing a back surface side of a wafer having ruggedness on a front surface side includes a protective member disposing step of putting a protective member in close contact with the front surface side of the wafer along the ruggedness and covering the front surface side of the wafer with the protective member, a processing step of holding the protective member side of the wafer by a chuck table and processing the back surface side of the wafer, a protective member peeling step of peeling off the protective member from the front surface side of the wafer, and a residue determination step of determining whether or not a residue of the protective member is present on the front surface side of the wafer and recording a determination result on the wafer basis.

### BACKGROUND OF THE INVENTION

### Field of the Invention

The present invention relates to a wafer processing method for covering a wafer with a protective member and processing the wafer.

### Description of the Related Art

In a manufacturing process of device chips, a wafer formed with devices in a plurality of regions partitioned by a plurality of streets arranged in a grid pattern is used. The wafer is divided along the streets, whereby a plurality of device chips including the devices respectively are obtained. The device chips are assembled into various electronic apparatuses such as mobile phones and personal computers.

For the cutting of the wafer, for example, a cutting apparatus is used. The cutting apparatus includes a holding table that holds a workpiece, and a cutting unit to which an annular cutting blade for cutting the workpiece is mounted. The wafer is held by the holding table and the cutting blade is rotated and is made to cut into the wafer, whereby the wafer is cut and divided. In recent years, attendant on a reduction in size of electronic apparatuses, thinning of device chips has been demanded. In view of this, processing for thinning the wafer may be performed before dividing the wafer. For the thinning of the wafer, a grinding apparatus is used which includes a holding table that holds the workpiece and a grinding unit to which a grinding wheel including a plurality of grindstones is mounted. The wafer is held by the holding table and the grindstone are put into contact with the wafer while rotating the holding table and the grinding wheel respectively, whereby the wafer is ground and thinned.

When grinding the wafer by the grinding apparatus, the devices formed on the front surface side of the wafer are covered with a protective member. Then, the front surface side of the wafer is held by the holding table with the protective member therebetween, and the back surface side of the wafer is ground. As a result, the wafer is processed in a state in which the devices are protected with the protective member, so that damaging of the devices during processing is prevented. In addition, deposition of the swarf (processing swarf) generated by the processing of the wafer onto the devices is obviated. However, the wafer often has ruggedness (projections and recesses) on the front surface side. For example, the devices formed on the front surface side of the wafer may include projections such as bumps projecting from the surfaces of the devices. In this case, ruggedness is formed on the front surface side of the wafer by the projections. Then, when the front surface side of the wafer is covered with the protective member, the protective member is deformed along the ruggedness of the wafer, and the ruggedness of the wafer is reflected on the protective member. As a result, the wafer becomes less liable to be uniformly held by the holding table of the processing apparatus, so that defective processing is liable to be generated.

In view of this, a material and a thickness of the protective member may be selected such that the projections formed on the front surface side of the wafer are embedded in the protective member when the protective member is attached to the wafer (see Japanese Patent Laid-open No. 2019-169727). When such a protective member is used, although the one surface side of the protective member is deformed along the ruggedness of the wafer, the other surface side of the protective member is kept in a flat state, and the ruggedness of the wafer is absorbed by the protective member. As a result, the wafer can be uniformly held by the holding table of the processing apparatus, and generation of defective processing is restrained.

### SUMMARY OF THE INVENTION

As the protective member for protecting the wafer, for example, a protective tape including a base material and an adhesive (glue layer) on the base material is used. The protective tape is attached to the wafer such that the adhesive side makes contact with the front surface side of the wafer, and the projections of the wafer are embedded in the adhesive. Then, the wafer is conveyed to a processing apparatus in a state in which the tape is attached thereto, and is held by the holding table with the tape therebetween. After processing of the wafer is completed, the protective tape is peeled off from the wafer, and is removed. In this instance, a portion of the adhesive of the protective tape may be left on the front surface side of the wafer. Then, when the device chips are manufactured by dividing the wafer in the state in which the residue of the adhesive is left thereon, the quality of the device chips is lowered. For example, when a portion of the adhesive is left in the state of being deposited on the bump of the device, defective connection of the bump may be generated when the device chip obtained by the division of the wafer is mounted to a mounting substrate.

On the other hand, a method of using a protective sheet not including an adhesive as a protective member, in place of the above-mentioned protective tape, has also been investigated. For example, a protective sheet including a thermoplastic resin is put into close contact with the front surface of the wafer in a heated and softened state, whereby the protective sheet is fixed to the wafer. When the protective sheet not including an adhesive is used, the adhesive is not left on the wafer when the protective sheet is peeled off from the wafer and is removed. Therefore, a lowering in the quality of device chips due to the residue of the adhesive is obviated. However, since the protective sheet makes close contact with the wafer, a portion of the protective sheet may be slightly left on the front surface side of the wafer, even after the protective sheet is peeled off from the wafer. Then, when processing of the wafer is proceeded without knowing the presence of the residue of the protective sheet on the wafer, a lowering in the quality of the device chips may occur, like in the case of using the protective tape.

The present invention has been made in consideration of the above problem. It is an object of the present invention to provide a wafer processing method with which it can be possible to determine whether or not a residue of a protective member is present on a wafer.

In accordance with an aspect of the present invention, there is provided a wafer processing method for processing a back surface side of a wafer having ruggedness on a front surface side. The wafer processing method includes a protective member disposing step of putting the protective member into close contact with the front surface side of the wafer along the ruggedness and covering the front surface side of the wafer with the protective member, a processing step of holding the protective member side of the wafer by a chuck table and processing the back surface side of the wafer, after the protective member disposing step is carried out, a protective member peeling step of peeling off the protective member from the front surface side of the wafer, after the processing step is carried out, and a residue determination step of determining whether or not a residue of the protective member is present on the front surface side of the wafer and recording a determination result on the wafer basis, after the protective member peeling step is carried out.

Note that, preferably, in the protective member disposing step, the protective member including a thermoplastic resin is heated and softened and is put into close contact with the front surface side of the wafer. In addition, preferably, the wafer processing method further includes a residue removing step of removing the residue from the front surface side of the wafer in the case where it is determined that the residue is present on the front surface side of the wafer in the residue determination step. Besides, preferably, in the residue determination step, a position of the residue in the wafer is recorded in the case where it is determined that the residue is present on the front surface side of the wafer. In addition, preferably, the protective member includes a fluorescent agent or a coloring agent.

In the wafer processing method according to one mode of the present invention, it is determined whether or not a residue of the protective member is present, after the protective member is peeled off from the wafer. As a result, it becomes possible to perform a suitable treatment according to the presence or absence of the residue of the protective member, and a device chip in a state in which the residue of the protective member is deposited can be prevented from being assembled into a product.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a wafer;

FIG. 2 is a perspective view depicting the wafer and a protective member;

FIG. 3A is a sectional view depicting a sheet contact unit;

FIG. 3B is a sectional view depicting the sheet contact unit in a state in which the sheet is in contact with the wafer;

FIG. 4 is a sectional view depicting a heating unit;

FIG. 5 is a sectional view depicting a cutting unit;

FIG. 6 is a front view depicting a grinding apparatus;

FIG. 7A is a perspective view depicting the wafer supported by a frame;

FIG. 7B is a perspective view depicting the wafer from which the protective member is peeled off;

FIG. 8 is a partly sectional front view depicting a determination unit;

FIG. 9 is a perspective view depicting the wafer having devices on which a residue of the protective member is deposited; and

FIG. 10 is a partly sectional front view depicting a cleaning unit.

### DETAILED DESCRIPTION OF THE PREFERRED EMBODIMENT

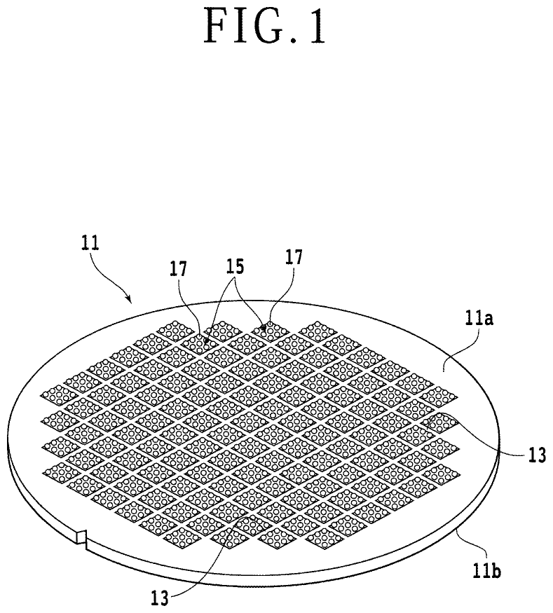

An embodiment according to one mode of the present invention will be described below referring to the attached drawings. First, a configuration example of a wafer processed by a wafer processing method according to the present invention will be described. FIG. 1 is a perspective view depicting a wafer 11.

The wafer 11 is, for example, a disk-shaped substrate including a semiconductor such as silicon, and has a front surface (first surface) 11a and a back surface (second surface) 11b which are substantially parallel to each other. The wafer 11 is partitioned into a plurality of rectangular regions by a plurality of streets 13 arranged in a grid pattern such as to intersect each other. On the front surface 11a side of the plurality of regions partitioned by the streets 13, devices 15 such as an integrated circuit (IC), large scale integration (LSI), a light emitting diode (LED), and micro electro mechanical systems (MEMS) are formed. Note that a material, a shape, a structure, a size, and the like of the wafer 11 are not limited. For example, the wafer 11 may be a substrate (wafer) of other semiconductor than silicon (GaAs, SiC, InP, GaN, etc.), sapphire, glass, ceramic, resin, metal, or the like. In addition, a kind, a number, a shape, a structure, a size, a layout, and the like of the devices 15 are not limited.

The devices 15 include a plurality of projections (structures) 17 projecting from the front surfaces of the devices 15. For example, the projections 17 are spherical connection electrodes (bumps) of a metallic material such as solder, and are connected to other electrodes or the like inside the devices 15. The plurality of projections 17 form ruggedness (projections and recesses) on the front surface 11a side of the wafer 11. Specifically, the regions where the projections 17 are present on the front surface 11a side of the wafer 11 correspond to projections, and the regions where the projections 17 are not present on the front surface 11a side of the wafer 11 correspond to recesses. In addition, terminals, wirings and circuits included in the devices 15, an insulating layer formed on the front surface 11a side of the wafer 11, or the like may form ruggedness.

The wafer 11 is subjected to various kinds of processing. For example, when the wafer 11 is divided along the streets 13, a plurality of device chips respectively including the devices are manufactured. In addition, when the wafer 11 is ground to be thinned before dividing the wafer 11, thinned device chips can be obtained. A specific example of the processing method for the wafer 11 will be described below. Here, as an example, a case where the back surface 11b side of the wafer 11 is ground will be described.

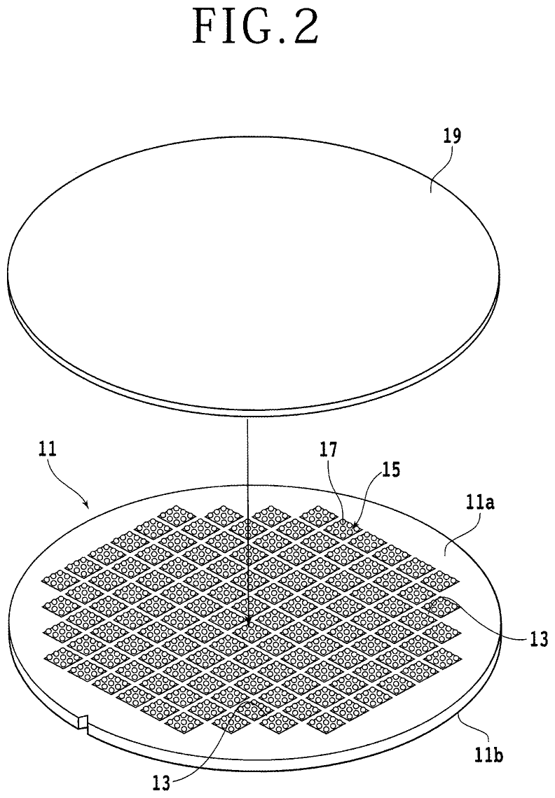

FIG. 2 is a perspective view depicting the wafer 11 and a protective member 19. When processing the wafer 11, first, the protective member 19 is put into close contact with the wafer 11 (protective member disposing step). The protective member 19 is a member for protecting the wafer 11 at the time of processing the wafer 11. For example, when subjecting the back surface 11b side of the wafer 11 to grinding, the protective member 19 is provided on the front surface 11a side of the wafer 11.

As the protective member 19, a sheet (protective sheet) including a thermoplastic resin and not including an adhesive (glue layer) can be used. When the protective sheet is put into contact with the wafer 11 and is softened by heating, the protective sheet is brought into close contact with the wafer 11. In addition, as the protective member 19, a tape (protective tape) including an adhesive (glue layer) can also be used. The protective tape includes a film-shaped base material, and an adhesive agent on the base material. For example, the base material includes a resin such as polyolefin, polyvinyl chloride, and polyethylene terephthalate, while the adhesive includes an epoxy, acrylic, or rubber adhesive. In addition, as the adhesive, an ultraviolet (UV) curing type resin which cures by irradiation with UV rays may also be used.

The protective member 19 is put into close contact with the wafer 11 such as to cover the whole part of the front surface 11a side of the wafer 11. As a result, the front surface 11a side of the wafer 11 and the plurality of devices 15 are protected by the protective member 19.

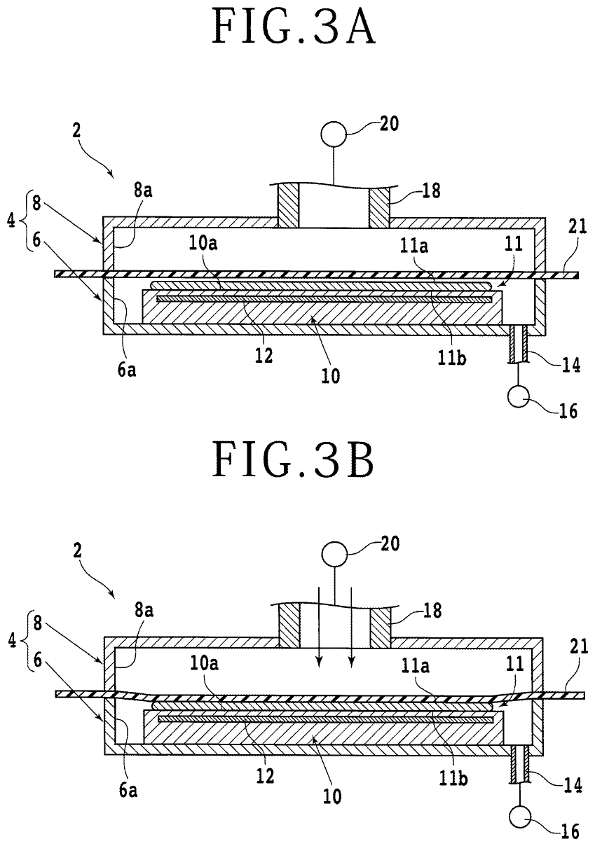

A specific example of the protective member disposing step will be described below. FIG. 3A is a sectional view depicting a sheet contact unit 2. In the protective member disposing step, first, a sheet (film) 21 is put into contact with the wafer 11 by use of the sheet contact unit 2.

The sheet contact unit 2 includes a rectangular parallelepiped chamber 4 capable of accommodating the wafer 11. For example, the chamber 4 includes a rectangular parallelepiped main body section 6 and a lid section 8 which are separable from each other. The main body section 6 includes a rectangular parallelepiped space (a recess, an opening section) 6a opening on an upper end side of the main body section 6. In addition, the lid section 8 includes a rectangular parallelepiped space (a recess, an opening section) 8a opening on a lower end side of the lid section 8. When the main body section 6 and the lid section 8 are laid on each other to close the main body section 6 with the lid section, the spaces 6a and 8a inside the chamber 4 are hermetically sealed.

In the inside (space 6a) of the main body section 6, a holding table (chuck table) 10 for holding the wafer 11 is provided. An upper surface of the holding table 10 constitutes a flat holding surface 10a for holding the wafer 11. Note that a height of the holding table 10 is adjusted such that when the wafer 11 is disposed on the holding table 10, an upper surface of the wafer 11 is positioned slightly below an upper end of the main body section 6. In addition, inside the holding table 10, a heat source (heater) 12 for heating the holding table 10 is provided.

The space 6a in the main body section 6 is connected to a suction source 16 such as an ejector, through a flow channel connected to a bottom wall of the main body section 6. Besides, the space 8a in the lid section 8 is connected to a suction source 20 such as an ejector, through a flow channel 18 connected to an upper wall of the lid section 8.

When the sheet 21 is put into close contact with the wafer 11 by use of the sheet contact unit 2, first, the lid section 8 is spaced from the main body section 6, and the space 6a of the main body section 6 is exposed. Then, the wafer 11 is conveyed to the space 6a of the main body section 6 and is held by the holding table 10. In this instance, the wafer 11 is disposed on the holding surface 10a of the holding table 10 such that the surface side (front surface 11a side) with which the sheet 21 is to be put in close contact is exposed to the upper side. Next, the sheet 21 is disposed on the main body section 6. The sheet 21 is a sheet capable of being fixed to the wafer 11 by heating. Specifically, the sheet 21 is a flexible sheet including a thermoplastic resin lower than the wafer 11 in melting point, and does not include an adhesive (glue layer). For example, as the sheet 21, a polyolefin (PO)-based sheet or a polyester (PE)-based sheet is used.

The polyolefin-based sheet is a sheet including a polymer synthesized with an alkene as a monomer. Examples of the polyolefin-based sheet includes polyethylene sheet, polypropylene sheet, polystyrene sheet, and the like. In addition, a sheet including a copolymer of propylene and ethylene and a sheet including an olefin-based elastomer can also be used. Polyester-based sheet is a sheet including a polymer synthesized with a dicarboxylic acid (a compound having two carboxylic groups) and a diol (a compound having two hydroxyl groups) as monomers. Examples of the polyester-based sheet includes polyethylene terephthalate sheet, polyethylene naphthalate sheet, and the like. Besides, polytrimethylene terephthalate sheet, polybutylene terephthalate sheet, or polybutylene naphthalate sheet can also be used.

The sheet 21 is formed in a shape and a size such as to be able to cover the whole body of the space 6a of the main body section 6 and the space 8a of the lid section 8. The sheet 21 is disposed on the upper end side of the main body section 6 such as to cover the space 6a of the main body section 6. Thereafter, the lid section 8 is disposed on the main body section 6. As a result, the sheet 21 is clamped between the main body section 6 and the lid section 8, and the space 6a and the space 8a are separated from each other. In addition, the space 6a and the space 8a are hermetically sealed with the sheet 21.

Next, a gas present in the space 6a of the main body section 6 is discharged by the suction source 16, and a gas present in the space 8a of the lid section 8 is discharged by the suction source 20. As a result, the space 6a and the space 8a are put into a reduced pressure state. Thereafter, the lid section 8 is opened to the atmosphere, permitting atmospheric air to flow from the exterior of the lid section 8 into the space 8a through the flow channel 18. By this, the pressure inside the space 8a rises, and a large pressure difference is generated between the space 6a and the space 8a. As a result, the sheet 21 is pressed against the wafer 11 side, and is put into contact with the front surface 11a side of the wafer 11.

FIG. 3B is a sectional view depicting the sheet contact unit 2 in a state in which the sheet 21 is in contact with the wafer 11. The sheet 21 makes contact with the wafer 11 along the ruggedness on the front surface 11a side of the wafer 11. Specifically, the thickness of the sheet 21 is larger than the projection amount of the projections 17 (see FIG. 1) projecting from the devices 15. The lower surface side of the sheet 21 is deformed such that the plurality of projections 17 are embedded in the sheet 21. On the other hand, the upper surface side of the sheet 21 is maintained in a flat state. Note that when the sheet 21 is brought into contact with the wafer 11, it is preferable to heat the holding table 10 and the wafer 11 by the heat source 12. As a result, when the sheet 21 comes into contact with the wafer 11, the sheet 21 is heated and softened, and is liable to be deformed along the ruggedness on the front surface 11a side of the wafer 11. Thereafter, the lid section 8 is opened, and the wafer 11 in a state in which the sheet 21 is in contact therewith is taken out from the chamber 4. Then, the wafer 11 and the sheet 21 are conveyed to a heating unit.

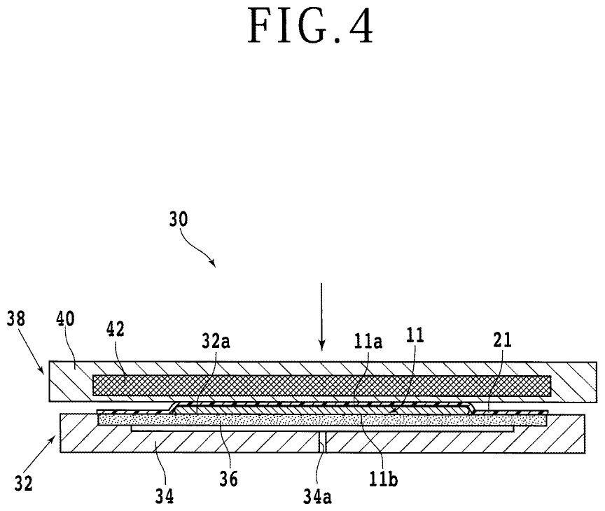

FIG. 4 is a sectional view depicting the heating unit 30. The heating unit 30 heats and softens the sheet 21, thereby putting the sheet 21 into close contact with the wafer 11. The heating unit 30 includes a holding table (chuck table) 32 that holds the wafer 11. For example, the holding table 32 includes a cylindrical frame body 34. The frame body 34 is provided at a central portion on an upper surface side with a cylindrical recess (groove), and a disk-shaped holding member 36 including a porous material such as a porous ceramic is fitted in the recess. An upper surface of the frame body 34 and an upper surface of the holding member 36 constitute a flat holding surface 32a that holds the wafer 11. The holding member 36 is provided therein with flow channels (pores) communicating from an upper surface to a lower surface of the holding member 36. The holding member 36 is connected to a suction source (not illustrated) such as an ejector through a flow channel 34a formed inside the frame body 34, a valve (not illustrated) and the like.

A pressing member (plate) 38 is provided on an upper side of the holding table 32. The pressing member 38 includes a cylindrical frame body 40 including a metal or the like. The frame body 40 is formed in a shape and a size such as to be able to cover the whole body of the wafer 11. For example, the frame body 40 is formed in a disk shape corresponding to the shape of the wafer 11, and the diameter of the frame body 40 is set equal to or larger than the diameter of the wafer 11. In addition, the frame body 40 is provided therein with a heat source (heater) 42 for heating the frame body 40. When electric power is supplied to the heat source 42, the heat source 42 generates heat, whereby the frame body 40 is heated. A lift mechanism (not illustrated) that lifts the pressing member 38 upward and downward is connected to the pressing member 38. With the pressing member 38 lifted upward and downward by the lift mechanism, the pressing member 38 is relatively moved away from and toward the holding table 32.

The wafer 11 is disposed on the holding table 32 such that the front surface 11a side (the sheet 21 side) faces the pressing member 38 and the back surface 11b side faces the holding surface 32a. In addition, the sheet 21 is disposed such as to cover the upper surface of the holding member 36. When a negative pressure of the suction source is made to act on the holding surface 32a in this state, the wafer 11 and the sheet 21 are suction held by the holding table 32. Next, the pressing member 38 is moved downward while heating the frame body 40 by the heat source 42, to press the pressing member 38 against the sheet 21. As a result, the sheet 21 is pressed against the front surface 11a side of the wafer 11 in a heated and softened state.

For example, the sheet 21 is heated to a temperature of equal to or higher than the softening point of the sheet 21 and equal to or lower than the melting point of the sheet 21. As a result, the sheet 21 is thermocompression bonded to the front surface 11a side of the wafer 11, and is attached to the wafer 11. It is to be noted, however, that the sheet 21 does not have a clear softening point. In this case, for example, the sheet 21 is heated to a temperature which is equal to or higher than a temperature lower than the melting point of the sheet 21 by a predetermined temperature (for example, on approximately 20° C.) and which is equal to or lower than the melting point of the sheet 21. In the case where the sheet 1 is a polyethylene sheet, for example, the sheet 21 is heated to a temperature of 120° C. to 140° C. In the case where the sheet 21 is a polypropylene sheet, for example, the sheet 21 is heated to a temperature of 160° C. to 180° C. In the case where the sheet 21 is a polystyrene sheet, for example, the sheet 21 is heated to a temperature of 220° C. to 240° C. In the case where the sheet 21 is a polyethylene terephthalate sheet, for example, the sheet 21 is heated to a temperature of 250° C. to 270° C. In the case where the sheet 21 is a polyethylene naphthalate sheet, for example, the sheet 21 is heated to a temperature of 160° C. to 180° C.

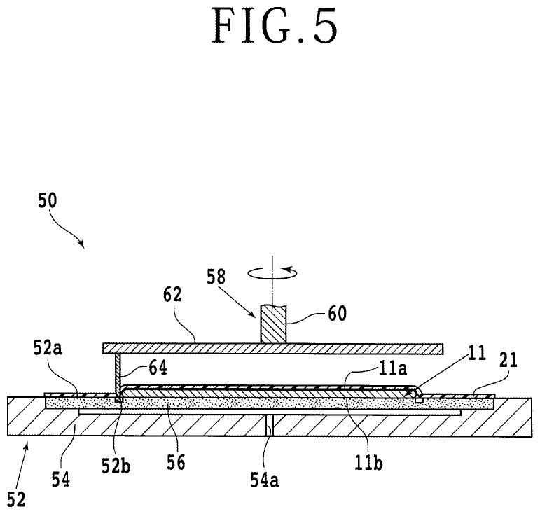

Next, the sheet 21 is cut along a peripheral edge (side surface) of the wafer 11. For example, the sheet 21 is cut by a cutting unit. FIG. 5 is a sectional view depicting the cutting unit 50.

The cutting unit 50 includes a holding table (chuck table) 52 that holds the wafer 11. For example, the holding table 52 includes a cylindrical frame body 54. The frame body 54 is provided at a central portion on an upper surface side with a cylindrical recess (groove), and a disk-shaped holding member 56 including a porous material such as a porous ceramic is fitted in the recess. An upper surface of the frame body 54 and an upper surface of the holding member 56 constitutes a flat holding surface 52a that holds the wafer 11. The holding member 56 is provided therein with flow channels (pores) communicating from an upper surface to a lower surface. The holding member 56 is connected to a suction source (not illustrated) such as an ejector through a flow channel 54a formed inside the frame body 54, a valve (not illustrated), and the like.

On an upper side of the holding table 52, a sheet cutting unit 58 for cutting the sheet 21 is provided. The sheet cutting unit 58 includes a cylindrical spindle 60 disposed along the vertical direction. A disk-shaped support member 62 is fixed to a tip end portion (lower end portion) of the spindle 60. A rotational drive source (not illustrated) such as a motor for rotating the spindle 60 around a rotational axis substantially parallel to the vertical direction is connected to a base end portion (upper end portion) of the spindle 60. A cutting blade (cutter) 64 for cutting the sheet 21 is mounted to a peripheral portion of the support member 62. The cutting blade 64 is disposed such that its lower end portion overlaps with a peripheral edge of the wafer 11 or a region on the slightly radial directionally outer side of the wafer than the peripheral edge of the wafer 11. In addition, a lift mechanism (not illustrated) for lifting the sheet cutting unit 58 upward and downward along the vertical direction is connected to the sheet cutting unit 58. When the spindle 60 is rotated by the rotational drive source, the support member 62 and the cutting blade 64 are rotated around the rotational axis substantially parallel to the vertical direction. In addition, the position of the rotational axis of the support member 62 is set to coincide with a center of the holding table 52 (center of the wafer 11). The cutting blade 64 is rotated along an annular path overlapping with the peripheral edge of the wafer 11.

After the sheet 21 is put into close contact with the wafer 11 by the heating unit 30 (see FIG. 4), the wafer 11 is conveyed to the cutting unit 50. Then, the wafer 11 is disposed on the holding table 52 such that the front surface 11a side (sheet 21 side) thereof faces the sheet cutting unit 58 and the back surface 11b side thereof faces the holding surface 52a. Besides, the sheet 21 is disposed such as to cover the upper surface of the holding member 56. When a negative pressure of the suction source is made to act on the holding surface 52a in this state, the wafer 11 and the sheet 21 are suction held by the holding table 32.

Next, while rotating the cutting blade 64, the sheet cutting unit 58 is lowered. Note that the holding table 52 is formed on the holding surface 52a side with an annular groove 52b overlapping with the track of the cutting blade 64. Then, the sheet cutting unit 58 is lowered such that the lower end of the cutting blade 64 is inserted into the groove 52b. When the cutting blade 64 comes into contact with the sheet 21, the sheet 21 is annularly cut along the peripheral edge of the wafer 11. As a result, that region of the sheet 21 which is on the outer side than the peripheral edge of the wafer 11 is removed. As a result, the wafer 11 in a state in which a circular sheet 21 functioning as a protective member 19 (see FIG. 2) is fixed thereto is obtained.

Note that the method for fixing the protective member 19 to the wafer 11 is not limited. For example, a circular protective member 19 formed to be substantially equal in diameter to the wafer 11 may be preliminarily prepared, and the protective member 19 may be adhered to the front surface 11a side of the wafer 11.

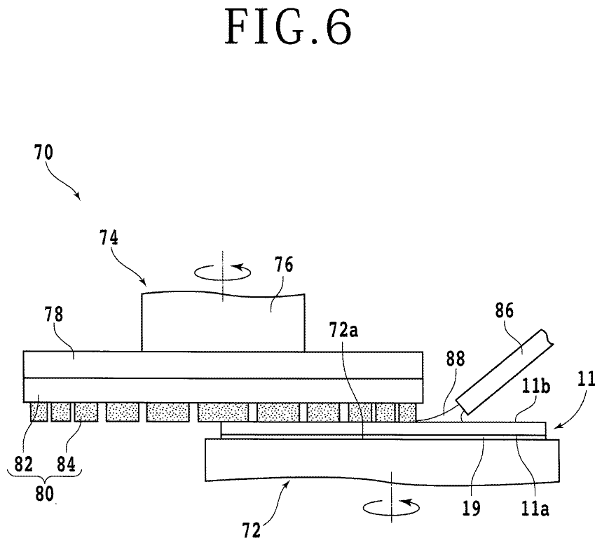

Next, the back surface 11b side of the wafer 11 is processed (processing step). For example, the back surface 11b side of the wafer 11 is ground, whereby the wafer 11 is thinned. For grinding of the wafer 11, a grinding apparatus is used. FIG. 6 is a front view depicting the grinding apparatus 70. The grinding apparatus 70 includes a holding table (chuck table) 72 that holds the wafer 11, and a grinding unit 74 that grinds the wafer 11.

An upper surface of the holding table 72 constitutes a flat holding surface 72a that holds the wafer 11. The holding surface 72a is connected to a suction source (not illustrated) such as an ejector through a flow channel (not illustrated) formed inside the holding table 72, a valve (not illustrated), and the like. In addition, a ball screw type moving mechanism (not illustrated) that moves the holding table 72 along a horizontal direction and a rotational drive source (not illustrated) such as a motor for rotating the holding table 72 around a rotational axis substantially parallel to the vertical direction are connected to the holding table 72.

On an upper side of the holding table 72, the grinding unit 74 is disposed. The grinding unit 74 includes a cylindrical spindle 76 disposed along the vertical direction. A disk-shaped mount 78 is fixed to a tip end portion (lower end portion) of the spindle 76. In addition, a rotational drive source (not illustrated) such as a motor for rotating the spindle 76 is connected to a base end portion (upper end portion) of the spindle 76. A grinding wheel 80 that grinds the wafer 11 is mounted to a lower surface side of the mount 78. The grinding wheel 80 includes an annular base 82 including a metal such as stainless steel and aluminum and formed to be substantially equal in diameter to the mount 78. Besides, a plurality of grindstones 84 are fixed to a lower surface side of the base 82. For example, the plurality of grindstones 84 are rectangular parallelepiped in shape, and are arranged substantially at regular intervals along the periphery of the base 82.

The grinding wheel 80 is rotated around a rotational axis substantially parallel to the vertical direction, by power transmitted from the rotational drive source through the spindle 76 and the mount 78. In addition, a ball screw type moving mechanism (not illustrated) that lifts the grinding unit 74 upward and downward along the vertical direction is connected to the grinding unit 74. Further, in the vicinity of the grinding unit 74, a nozzle 86 for supplying grinding liquid 88 such as pure water to the wafer 11 held on the holding table 72 and the plurality of grindstones 84 is provided.

When grinding the wafer 11, first, the wafer 11 is held by the holding table 72. Specifically, the wafer 11 is disposed on the holding table 72 such that the front surface 11a side (protective member 19 side) thereof faces the holding surface 72a, and the back surface 11b side thereof is exposed to the upper side. When a negative pressure of the suction source is made to act on the holding surface 72a in this state, the front surface 11a side of the wafer 11 is suction held on the holding table 72 with the protective member 19 interposed therebetween. Note that the projections 17 (see FIG. 1) formed on the front surface 11a side of the wafer 11 are embedded in the protective member 19. Therefore, the ruggedness (projections and recesses) on the front surface 11a side of the wafer 11 is absorbed by the protective member 19, and the wafer 11 is held by the holding surface 72a in a flat state.

Next, the holding table 72 is moved to a lower side of the grinding unit 74. Then, while rotating the holding table 72 and the grinding wheel 80 in respective directions at predetermined rotational speeds, the grinding wheel 80 is lowered toward the holding table 72. The lowering speed of the grinding wheel 80 in this instance is adjusted such that the plurality of grindstones 84 are pressed against the wafer 11 with an appropriate force. When the plurality of rotating grindstones 84 come into contact with the back surface 11b side of the wafer 11, the back surface 11b side of the wafer 11 is ground off. As a result, the wafer 11 is ground and is thinned. By the grinding liquid 88 supplied from the nozzle 86 during grinding of the wafer 11, the wafer 11 and the grindstones 84 are cooled, and swarf (grinding swarf) generated by grinding of the wafer 11 is washed away. Then, when the wafer 11 is thinned to a predetermined thickness (finish thickness), grinding of the wafer 11 is stopped.

Note that the contents of processing in the grinding step are not limited to the above-mentioned grinding. For example, cutting in which an annular cutting blade is made to cut into the back surface 11b side of the wafer 11 to cut the wafer 11, or laser processing in which a laser beam is applied to the back surface 11b side of the wafer 11 to process the wafer 11, may be conducted.

Subsequently, the protective member 19 is peeled off from the front surface 11a side of the wafer 11 (protective member peeling step). For example, in the protective member peeling step, the protective member 19 is peeled off from the wafer 11, in a state in which the wafer 11 is supported by an annular frame.

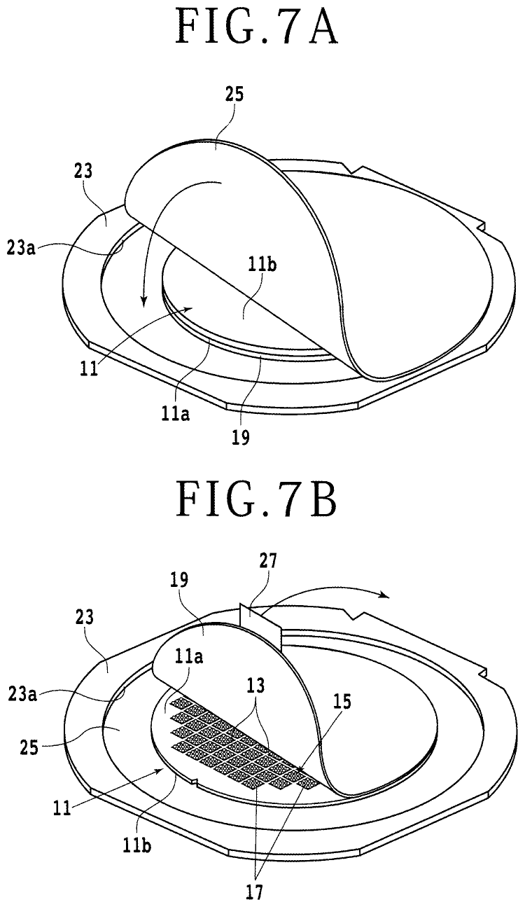

FIG. 7A is a perspective view depicting the wafer 11 supported by a frame 23. The wafer 11 processed in the processing step is disposed inside an annular frame 23 including a metal or the like. Specifically, the frame 23 is provided in its central portion with a circular opening 23a larger in diameter than the wafer 11. The wafer 11 is disposed inside the opening 23a. Next, a tape 25 is attached to the wafer 11 and the frame 23. For example, the tape 25 includes a circular base material and an adhesive (glue layer) on the base material. The tape 25 is attached to the wafer 11 and the frame 23 such that a central portion thereof makes contact with the back surface 11b side of the wafer 11, and a peripheral portion thereof makes contact with the frame 23. As a result, the wafer 11 is supported by the frame 23 through the tape 25.

Next, the protective member 19 is peeled off from the wafer 11. FIG. 7B is a perspective view depicting the wafer 11 from which the protective member 19 is peeled off. For example, first, a release tape 27 is attached to one end portion of the protective member 19. Then, the release tape 27 is moved toward the other end side of the protective member 19 in such a manner as to be spaced from the wafer 11. As a result, the end portion of the protective member 19 is separated from the wafer 11 following up to the release tape 27, and the protective member 19 is peeled off from the wafer 11. Note that, in the case where a sheet not including an adhesive is used as the protective member 19, the protective member 19 is merely in close contact with the wafer 11 and is not adhered to the wafer 11. Therefore, the protective member 19 can be easily peeled off from the wafer 11, without conducting a special treatment (immersion in a solution, irradiation with electromagnetic wave such as UV rays, etc.) for peeling off the protective member 19.

Here, when the protective member 19 is peeled off from the wafer 11, a portion of the protective member 19 may be left on the front surface 11a side of the wafer 11. For example, in the case where a tape including an adhesive is used as the protective member 19, a portion of the adhesive may be left on the front surface 11a side of the wafer 11. In addition, in the case where the protective member 19 is a sheet 21 (see FIG. 4) in close contact with the wafer 11, a portion of the sheet 21 may slightly be left on the front surface 11a side of the wafer 11. In view of this, in the present embodiment, after the protective member peeling step is carried out, it is determined whether or not the residue of the protective member 19 is present on the front surface 11a side of the wafer 11 (residue determination step).

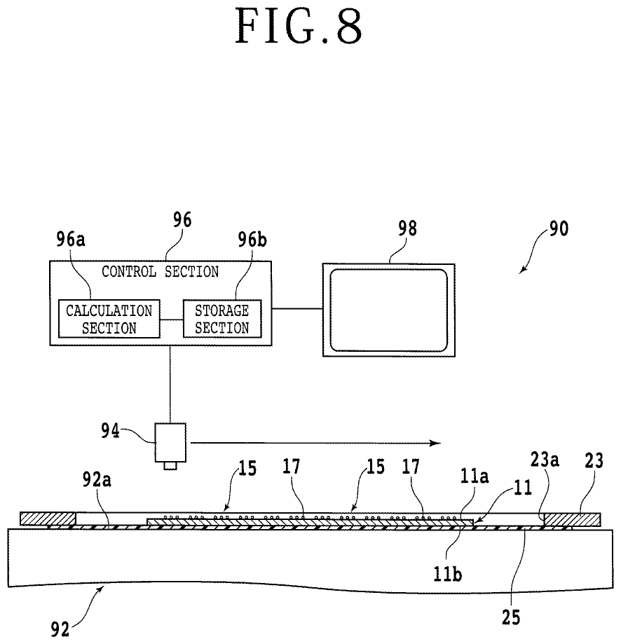

FIG. 8 is a partly sectional front view depicting a determination unit 90 that determines the presence or absence of residue of the protective member 19. The determination unit 90 includes a holding table (chuck table) 92 that holds the wafer 11. An upper surface of the holding table 92 constitutes a flat holding surface 92a that holds the wafer 11. The holding surface 92a is connected to a suction source such as an ejector, through a flow channel (not illustrated) formed inside the holding table 92, a valve (not illustrated), and the like.

On an upper side of the holding table 92, an imaging unit 94 that images the wafer 11 held by the holding table 92 is provided. For example, as the imaging unit 94, a visible light camera including an imaging element that receives visible light and converting it into an electrical signal, an infrared light camera including an imaging element that receives infrared light and converts it into an electrical signal, or the like is used. Besides, a moving mechanism (not illustrated) that moves the imaging unit 94 along horizontal directions is connected to the imaging unit 94.

In addition, the determination unit 90 includes a control section (control unit) 96 connected to the imaging unit 94. The control section 96 outputs a control signal to the imaging unit 94, thereby controlling the operations (imaging conditions, imaging timing, etc.) of the imaging unit 94. Besides, the control section 96 outputs a control signal to the moving mechanism (not illustrated) connected to the imaging unit 94, thereby controlling the position of the moving mechanism in horizontal directions. For example, the control section 96 is configured by a computer, which includes a calculation section 96a that performs various kind of arithmetic processing necessary for operation of the determination unit 90, and a storage section 96b in which various kinds of information (data, program, etc.) to be used for arithmetic processing by the calculation section 96a are stored. The calculation section 96a is configured to include a processor such as a central processing unit (CPU). Besides, the storage section 96b is configured to include various kinds of memories constituting a main storage device, an auxiliary storage device, and the like.

In addition, a display section (display unit) 98 that displays information concerning the wafer 11 is connected to the control section 96. For example, as the display section 98, a touch panel type display is used. In this case, the display section 98 functions as a user interface, and the operator can input information to the control section 96 by operating the display section 98. In other words, the display section 98 functions also as an input section (input unit).

It is determined by the determination unit 90 whether or not a residue of the protective member 19 is present on the front surface 11a side of the wafer 11. Specifically, first, the wafer 11 after peeling of the protective member 19 therefrom is held by the holding table 92. Note that the wafer 11 is disposed on the holding table 92 such that the front surface 11a side thereof is exposed to the upper side, and the back surface 11b side (the tape 25 side) thereof faces the holding surface 92a. When a negative pressure of the suction source is made to act on the holding surface 92a in this state, the wafer 11 is suction held by the holding table 92 with the tape 25 interposed therebetween. Next, the wafer 11 is imaged by the imaging unit 94, to acquire an image (picked-up image) representing the front surface 11a side of the wafer 11. In this instance, the position of the imaging unit 94 in horizontal directions is adjusted by the control section 96, whereby a region to be imaged of the wafer 11 can be selected. The picked-up image acquired by the imaging unit 94 is inputted to the control section 96. Then, the control section 96 determines whether or not the residue of the protective member 19 is present on the front surface 11a side of the wafer 11, based on the picked-up image.

For example, the control section 96 applies an image processing to the picked-up image, thereby determining the presence or absence of a residue of the protective member 19. Specifically, an image on the front surface 11a side of the wafer 11 free of the residue of the protective member 19 is preliminarily stored as a reference image in the storage section 96b of the control section 96. The control section 96 performs pattern patching of comparing the picked-up image inputted from the imaging unit 94 and the reference image stored in the storage section 96b, thereby calculating the degree of similarity between the picked-up image and the reference image. Thereafter, based on whether or not the degree of similarity exceeds a predetermined reference value (threshold), the control section 96 determines whether or not the residue of the protective member 19 is present on the front surface 11a side of the wafer 11.

Note that the protective member 19 may contain a fluorescent agent. For example, the protective member 19 may contain a fluorescent agent that emit light by absorbing electromagnetic waves such as UV rays. In this case, when the wafer 11 is imaged by the imaging unit 94 while applying electromagnetic waves to the wafer 11 with the residue of the protective member 19 deposited thereon, a picked-up image in which the residue of the protective member 19 is emphasized by light emission is obtained. In addition, the protective member 19 may contain a coloring agent. For example, the protective member 19 may contain a dye in a color different from those of the front surface 11a of the wafer 11 and the surfaces of the devices 15. In this case, when the wafer 11 with the residue of the protective member 19 deposited thereon is imaged by the imaging unit 94, a picked-up image in which the residue of the protective member 19 is emphasized by coloring is obtained. When the protective member 19 contains a fluorescent agent or a coloring agent, a region in which the residue of the protective member 19 is deposited, in the picked-up image, is represented in a tone different from a region where the residue of the protective member 19 is not deposited. Therefore, based on whether or not the picked-up image contains the image of the tone corresponding to the residue of the protective member 19, the control section 96 can determine the presence or absence of the residue of the protective member 19. Note that the fluorescent agent and the coloring agent may be contained inside the protective member 19, or may be applied to the surface of the protective member 19.

The imaging of the wafer 11 is preferably conducted by repeating an operation of imaging, in an enlarged form, a part of the wafer 11 by the imaging unit 94, while changing the position of the imaging unit 94 in horizontal directions. By synthesizing a plurality of enlarged images acquired by the imaging unit 94, a synthetic image in high resolution representing the whole region on the front surface 11a side of the wafer 11 is obtained. By using this synthetic image for determination of the presence or absence of the residue of the protective member 19, the detection accuracy of the protective member 19 can be enhanced.

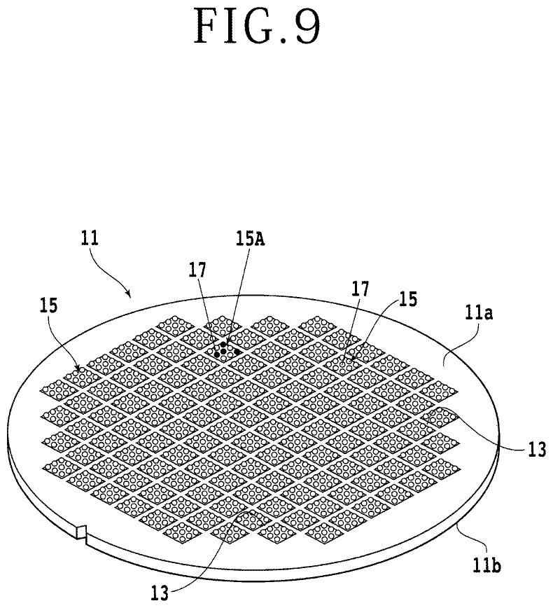

FIG. 9 is a perspective view depicting the wafer 11 having a device 15 on which the residue of the protective member 19 is deposited. A device 15A in FIG. 9 corresponds to a device 15 on which the residue of the protective member 19 is deposited on the projection 17. When the region in which the device 15A is formed of the wafer 11 is imaged by the imaging unit 94 (see FIG. 8), a picked-up image including the residue of the protective member 19 deposited on the projection 17 of the device 15A is acquired. When this picked-up image is inputted to the control section 96, the control section 96 determines that the residue of the protective member 19 is present on the wafer 11.

Then, the control section 96 records in the storage section 96b the result of determination of whether or not the residue of the protective member 19 is present on the front surface 11a side of the wafer 11. Note that, when a plurality of wafers 11 are inspected by the determination unit 90, the determination results are recorded on the wafer 11 basis. Further, in the case where the residue of the protective member 19 is detected, the control section 96 records the position of the residue in the wafer 11 in the storage section 96b. For example, the position of the residue is represented by the number indicating the position of the device 15 (device 15A) on which the residue is deposited. An example of information recorded in the residue determination step is set forth in Table 1.

TABLE 1

| | Presence or absence of | Position of |
|---|---|---|
| Wafer No. | residue | residue |
| 1 | Absent | — |
| 2 | Absent | — |
| 3 | Absent | — |
| 4 | Present | Device 5-3 |
| 5 | Absent | — |

The position of the residue can be specified based on the positional relation between the holding table 92 (wafer 11) and the imaging unit 94, at the time when the picked-up image including the residue of the protective member 19 is acquired by the imaging unit 94. For example, each time the imaging unit 94 images the wafer 11, position information concerning the imaging unit 94 at the time of imaging is inputted from the moving mechanism connected to the imaging unit 94 to the control section 96. Based on the position of the imaging unit 94, the control section 96 specifies the position of the device 15 on which the residue is deposited. Note that the position of the residue may be expressed in XY coordinates or the like.

As above-mentioned, the determination of the presence or absence of the residue in the residue determination step can be automatically performed by the control section 96. For example, a program describing a series of operations of imaging of the wafer 11 by the imaging unit 94, determination of the residue of the protective member 19 based on the picked-up image, recording of the determination results, and the like is stored in the storage section 96b of the control section 96. When the picked-up image is inputted from the imaging unit 94 to the control section 96, the calculation section 96a reads the program from the storage section 95b, and executes the program, to determine the residue of the protective member 19. As a result, determination of the presence or absence of the residue is performed easily and speedily.

Note that the determination results of the presence or absence of the residue of the protective member 19 by the control section 96 may be displayed on the display section 98. For example, the display section 98 displays the presence or absence of the residue and the position of the residue on the wafer 11 basis (see Table 1). As a result, the information concerning the residue of the protective member 19 is reported to the operator.

After the residue determination step is carried out, the wafer 11 is cut along the streets 13, to be divided into a plurality of device chips which include the devices 15 respectively. However, when the wafer 11 determined that the residue of the protective member 19 is present thereon is divided as it is, the plurality of device chips obtained by the division of the wafer 11 would include device chips of low quality that include the devices 15A on which the residue of the protective member 19 is deposited. For this reason, in the case where it is determined in the residue determination step that the residue of the protective member 19 is present on the wafer 11, it is preferable to carry out a step of removing the residue from the front surface 11a side of the wafer 11 (residue removal step). For example, in the residue removal step, the wafer 11 is cleaned to remove the residue of the protective member 19.

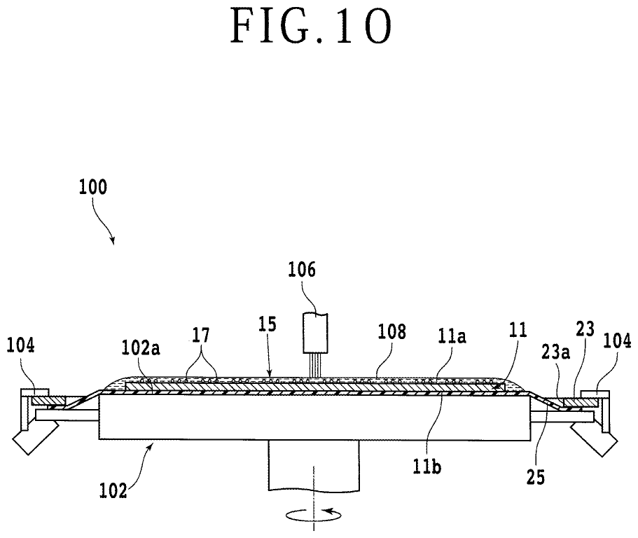

FIG. 10 is a partly sectional front view depicting a cleaning unit 100 for cleaning the wafer 11. The cleaning unit 100 includes a holding table (chuck table) 102 that holds the wafer 11. An upper surface of the holding table 102 constitutes a flat holding surface 102a that holds the wafer 11. The holding surface 102a is connected to a suction source (not illustrated) such as an ejector, through a flow channel (not illustrated) formed inside the holding table 102, a valve (not illustrated), and the like. A rotational drive source (not illustrated) such as a motor for rotating the holding table 102 around a rotational axis substantially parallel to the vertical direction is connected to the holding table 102. In addition, in the periphery of the holding table 102, a plurality of clamps 104 for fixing by grasping a frame 23 supporting the wafer 11 are provided.

On an upper side of the holding table 102, a nozzle 106 for supplying a cleaning fluid 108 toward the holding table 102 is provided. For example, as the fluid 108, a liquid such as pure water or a mixed fluid obtained by mixing a liquid such as pure water with a gas such as air is used.

The wafer 11 on which it is determined that the residue of the protective member 19 is present is conveyed to the cleaning unit 100. The wafer 11 is disposed on the holding table 102 such that the front surface 11a side thereof is exposed to the upper side and the back surface 11b side (tape 25 side) thereof faces the holding surface 102a. When a negative pressure of the suction source is made to act on the holding surface 102a in this state, the wafer 11 is suction held by the holding table 102 with the tape 25 interposed therebetween. Thereafter, when the fluid 108 is supplied from the nozzle 106 toward the wafer 11 while rotating the holding table 102, the fluid 108 supplied to a central portion of the wafer 11 flows along the front surface 11a side of the wafer 11, flowing toward the peripheral edge side of the wafer 11. As a result, the residue of the protective member 19 deposited on the front surface 11a side of the wafer 11 is washed away by the fluid 108, and is removed. Note that the conditions of cleaning (cleaning time, flow rate of the fluid 108, rotational speed of the holding table 102, etc.) are set such that the residue of the protective member 19 is removed.

As above-mentioned, by removing the residue of the protective member 19 before dividing the wafer 11, the residue of the protective member 19 can be prevented from being left. As a result, the yield of the device chips can be prevented from being lowered. Note that, instead of performing the residue removal step, the device chips on which the residue of the protective member 19 is deposited may be excluded from the device chips for products. Specifically, when the device chips are picked up and mounted on a mounting substrate after the division of the wafer 11, the device chips on which the residue of the protective member 19 is deposited are excluded from the objects of pick-up. Note that the device chips to be excluded can be specified based on the positions of the residue which are recorded in the storage section 96b (see FIG. 9) of the control section 96 in the residue determination step.

As above-mentioned, in the wafer processing method according to the present embodiment, it is determined whether or not the residue of the protective member 19 is present on the front surface 11a side of the wafer 11 after the protective member 19 is peeled off from the front surface 11a side of the wafer 11, and determination results are recorded. As a result, a suitable treatment (cleaning of the wafer 11, exclusion of the device chips on which the residue is deposited, etc.) can be performed according to the presence or absence of the residue of the protective member 19, and the device chips in a state in which the residue of the protective member 19 is deposited thereon can be prevented from being assembled into products.

Note that the structures, methods, and the like concerning the above embodiment can be appropriately modified within such scopes as not to depart from the scope of the object of the present invention.

The present invention is not limited to the details of the above described preferred embodiment. The scope of the invention is defined by the appended claims and all changes and modifications as fall within the scope of the claims are therefore to be embraced by the invention.

What is claimed is:

1. A wafer processing method for processing a back surface side of a wafer having ruggedness on a front surface side, the wafer processing method comprising:
a protective member disposing step of putting the protective member into close contact with the front surface side of the wafer along the ruggedness and covering the front surface side of the wafer with the protective member;
a processing step of holding the protective member side of the wafer by a chuck table and processing the back surface side of the wafer, after the protective member disposing step is carried out;
a protective member peeling step of peeling off the protective member from the front surface side of the wafer, after the processing step is carried out; and
a residue determination step of determining whether or not a residue of the protective member is present on the front surface side of the wafer and recording a determination result on the wafer basis, after the protective member peeling step is carried out.

2. The wafer processing method according to claim 1, wherein, in the protective member disposing step, the protective member including a thermoplastic resin is heated and softened and is put into close contact with the front surface side of the wafer.

3. The wafer processing method according to claim 1, further comprising:
a residue removing step of removing the residue from the front surface side of the wafer in a case where it is determined that the residue is present on the front surface side of the wafer in the residue determination step.

4. The wafer processing method according to claim 1, wherein, in the residue determination step, a position of the residue in the wafer is recorded in a case where it is determined that the residue is present on the front surface side of the wafer.

5. The wafer processing method according to claim 1, wherein the protective member includes a fluorescent agent or a coloring agent.
